(19) United States
(12) Patent Application Publication
(10) Pub. No.: US 2009/0170371 A1
(43) Pub. Date: Jul. 2, 2009

(54) USB DEVICE FOR A RING BINDER

(76) Inventor: Mark A. Bedol, Claremont, CA (US)

Correspondence Address: LAWRENCE N. GINSBERG, 21 SAN ANTONIO, NEWPORT BEACH, CA, 92660-9112, US

(21) Appl. No.: 11/966,308

(22) Filed: Dec. 28, 2007

(51) Int. Cl. H01R 13/648; H05K 5/02

(52) U.S. Cl. 439/607.01

(57) ABSTRACT

A USB device for a ring binder includes a main body including a first and a second opposing substantially planar surface so as to be easily accommodated in a ring binder. The main body has a cavity formed therein. A USB element is positioned within the cavity of the main body. A narrow flanged portion extends from the second planar surface of the main body. The narrow flanged portion includes a plurality of spaced openings extending therethrough. At least one of the openings is so sized to provide access to selected rings of a ring binder.

### BACKGROUND OF THE INVENTION

1. Field of the Invention

The present invention relates to inserts for notebooks and more particularly to a USB device which is adapted to be securable to the rings of a notebook.

2. Description of the Related Art

Users of notebooks, including businessmen and students, often desire to have various articles such as pencils and pens at their easy disposal when they use their notebook and to be secure from being lost when they carry their notebooks from one location to another.

In partial solution to this problem, present applicant Mark A. Bedol, invented a “Notebook Organizer Including Slidable Element”, U.S. Pat. No. 5,058,736. The '736 patent discloses an organizer comprising a base with holes for engagement with the rings of a ringed notebook. The base includes a plurality of partitions which divide the base into a plurality of compartments. The patent also discloses an electronic calculator having a longitudinal extension thereon being slidably engageable with, and supported between, opposing partition surfaces.

Present applicant Mark A. Bedol, has also invented “Notebook Insert With Calculator and Holepunch” U.S. Pat. No 5,209,592, which discloses a notebook insert comprising a housing, an electronic calculator attached to the housing and a holepunch assembly also attached to the housing. The housing has a periphery with multiple holes therethrough which are spaced to be adapted for engagement with the rings of a ringed notebook.

U.S. Pat. No. 5,409,319, issued to applicant Mark A. Bedol, entitled, “Notebook Insert with Holepunch,” discloses a notebook insert with a housing having a first rigid substantially flat plate having a first set of a number of spaced holes formed therethrough a first side thereof, the first set of holes being adapted for engagement with the rings of a ringed notebook. The housing further has a second set of a number of spaced holes formed therethrough a second side thereof. The housing further includes an opening in a central portion thereof. A number of spaced hinges are located on a side edge of the central portion defined by the opening. A second rigid plate has a first side hingedly connected via the spaced hinges to the first rigid plate. The second plate has a shape substantially matching the shape of the central opening so when the second rigid plate is in a stowed position it may be supported within the central opening. The second plate includes spaced projections formed on an upper surface thereof. The projections are so sized and spaced to align with the second set of spaced holes in the first plate when the second plate is rotated away from the stowed position so as to provide a holepunching capability when paper is inserted between the first plate and the second plate. Thus, the holepunch capability may be utilized without a need for removing the notebook insert from a binder it may be attached to.

U.S. Pat. No. Des. 354,770, entitled “Hole Punch for a Ring-Binder,” also by invented by applicant Bedol discloses a hole punch for a ring binder.

The Bedol related disclosed hole punches provide an efficient, inexpensive means for simultaneously minimizing the space taken in a notebook binder and being capable of punching paper while remaining attached to the rings of the binder.

U.S. Pat. No. 5,388,306, entitled “Eraser for a Ring Binder” issued to applicant Bedol discloses an eraser for a ring binder comprising an eraser element having at least one hole extending therethrough. The hole is sized so as to provide access to a ring of a ring binder. The eraser preferably has a triangle-like shape comprising a base, a first side, and a second side. The base is preferably curved so as to accommodate a notebook organizer of the type having an organizer base with a substantially flat bottom surface and with a plurality of holes being adapted for engagement with the rings of a ring notebook.

### SUMMARY OF THE INVENTION

In a broad aspect, the present invention is a USB device for a ring binder. The USB device includes a main body including a first and a second opposing substantially planar surface so as to be easily accommodated in a ring binder. The main body has a cavity formed therein. A USB element is positioned within the cavity of the main body. A narrow flanged portion extends from the second planar surface of the main body. The narrow flanged portion includes a plurality of spaced openings extending therethrough. At least one of the openings is so sized to provide access to selected rings of a ring binder.

Preferably, a first of the substantially planar surfaces is flat and a second of the planar surfaces comprises a longitudinal recessed portion. The recessed portion comprises first and second longitudinally spaced locking tabs. The flanged portion comprises a second of the openings being elongated to provide access to locking tabs of another USB device of same construction for locking engagement therewith, thereby allowing optimized stacking of a plurality of USB devices within a ring binder.

### BRIEF DESCRIPTION OF THE DRAWINGS

FIG. 1 is a perspective view of a first embodiment of the USB device of the present invention, shown inserted in a ring binder.

FIG. 2 is front perspective view of the USB device of FIG. 1.

FIG. 3 is rear perspective view of the USB device.

FIG. 4 is rear perspective view of three USB devices shown in a stacked arrangement.

FIG. 5 is a perspective view of another embodiment of the USB device with an LCD screen.

### DETAILED DESCRIPTION OF THE INVENTION

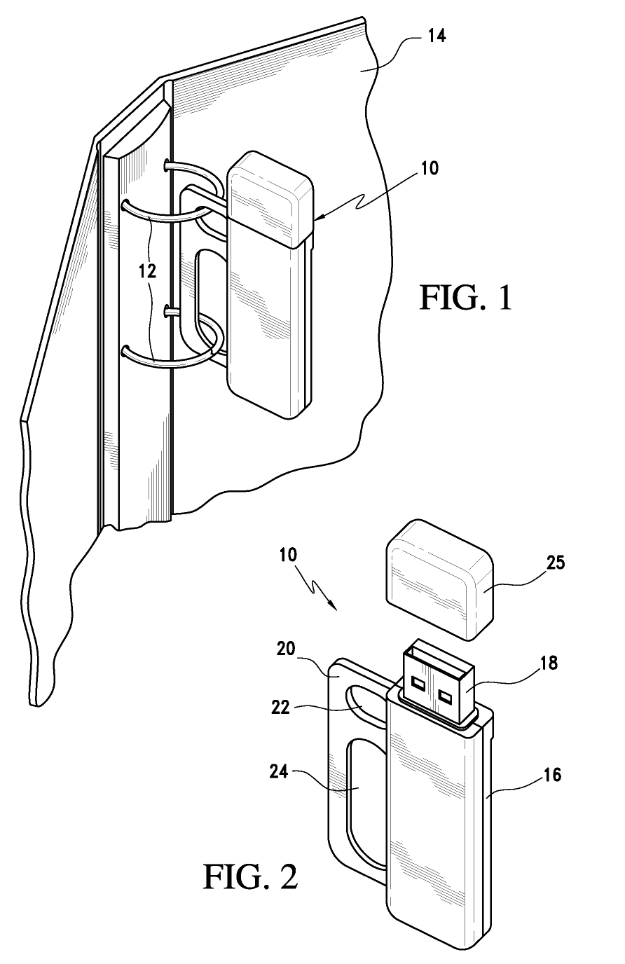

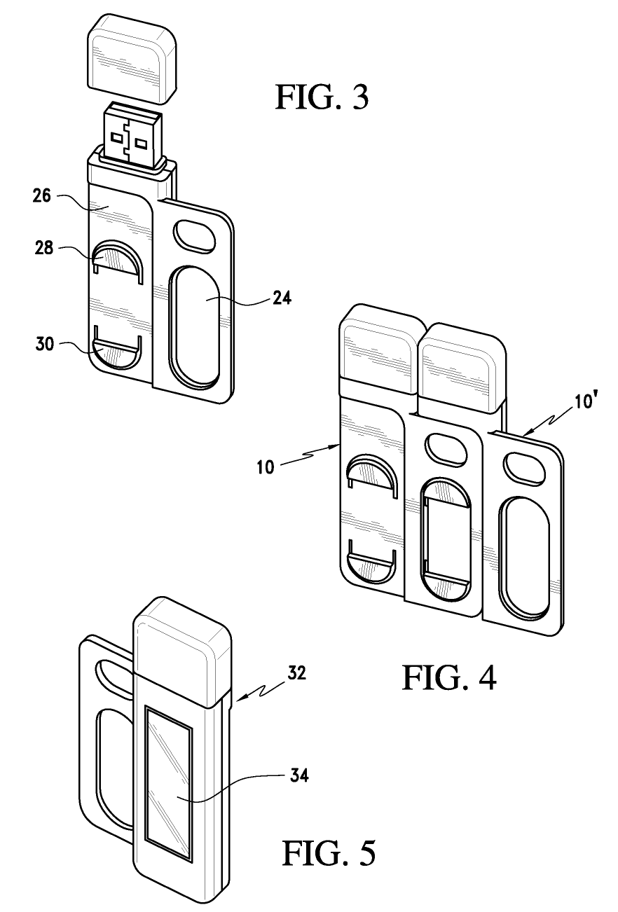

Referring to the drawings and the characters of reference marked thereon, FIG. 1 illustrates the USB device of the present invention, designated generally as 10, shown attached to the rings 12 of a conventional ring binder, designated generally as 14. As can be clearly in FIGS. 2-3 the USB device 10 includes a main body 16 including a first and a second opposing substantially planar surface so as to be easily accommodated in the ring binder 14. The main body has a cavity formed therein for containing a USB element 18. A narrow flanged portion 20 extends from one of the planar surfaces of the main body 16. The narrow flanged portion 20 includes two spaced openings 22, 24 extending therethrough. At least one of the openings is so sized to provide access to selected rings of the ring binder 14. Each USB device 10 includes a cap 25 for fitting over the end of the USB element.

As can be seen in FIG. 3, the back planar surface has a longitudinal recessed portion 26 that includes first and second longitudinally spaced locking tabs 28, 30. As can be seen in FIG. 4, the elongated opening 24 is stepped and provides access to locking tabs of another USB device of same construction for locking engagement therewith, thereby allowing optimized stacking of a plurality of USB devices 10, 10′ within a ring binder.

As the term “USB element” is used herein it is to be construed broadly to refer to a device that utilizes a USB connection. If used in a ring binder, as in the disclosed preferred embodiment, the USB element 18 is likely a memory stick, i.e. memory storage device, but may be any relatively thin, compact USB device that can be fitted within the ring binder, for example, an MP3 audio player, a digital audio recorder/player, an MP4 audio/video player/recorder, or a digital image player/frame playback device.

The main body 16 is preferably approximately between about ⅛ and ⅜ inch thick, most preferably about ¼ inch thick. This provides convenient use within a ring binder. If the devices are stacked space within the binder is optimized. The main body 16 is preferably formed of plastic material; however, it may be formed of metal or a glass or metal filled plastic.

Referring now to FIG. 5, a second embodiment of the present invention is illustrated in which the USB device is embodied as a digital picture frame playback device, designated generally as 32. The device 32 includes a small LCD screen 34 on the front surface thereof.

As discussed above the present invention can be added to the ring binder while also be effectively expanded by joining a desired number of additional devices to the initial one. Also, it does not matter which device starts the first part of the “chain”. All of them are interchangeable.

Other embodiments and configurations may be devised without departing from the spirit of the invention and the scope of the appended claims. For example, even though the principles of this invention are particularly adapted for use with ring binders the construction of flanges, opening(s) and tabs provides the ability to stack these USB devices even without utilization within a ring binder.

Furthermore, although discussed relative to a number of USB devices, other stackable devices of similar construction may be stacked with a USB device. Such stackable devices should each include a main body with opposing surfaces and a narrow flanged portion flanged portion with elongated openings to provide access to locking tabs of another stackable device of similar construction for locking engagement therewith.

1. A USB device for a ring binder, comprising:
a) a main body comprising a first and a second opposing substantially planar surface so as to be easily accommodated in a ring binder, said main body having a cavity formed therein;
b) a USB element positioned within said cavity of said main body; and,
c) a narrow flanged portion extending from said second planar surface of said main body, said narrow flanged portion comprising a plurality of spaced openings extending therethrough, at least one of said openings being so sized to provide access to selected rings of a ring binder.

2. The USB device of claim 1, wherein:
a) a first of said substantially planar surfaces is flat and a second of said planar surfaces comprises a longitudinal recessed portion, said recessed portion comprising first and second longitudinally spaced locking tabs; and,
b) said flanged portion comprises a second of said openings being elongated to provide access to locking tabs of another USB device of same construction for locking engagement therewith, thereby allowing optimized stacking of a plurality of USB devices within a ring binder.

3. The USB device of claim 2, wherein said second of said openings is stepped.

4. The USB device of claim 1, further comprising a cap for fitting over the end of said USB element.

5. The USB device of claim 1, wherein said USB element comprises a memory storage device.

6. The USB device of claim 1, wherein said USB element comprises a digital picture frame playback device.

7. A system of stackable USB devices for use with a ring binder, comprising:
a plurality of USB devices, each USB device comprising:
a) a main body comprising a first and a second opposing substantially planar surface so as to be easily accommodated in a ring binder, said main body having a cavity formed therein;
b) a USB element positioned within said cavity of said main body; and,
c) a narrow flanged portion extending from said second planar surface of said main body, said narrow flanged portion comprising a plurality of spaced openings extending therethrough, at least one of said openings being so sized to provide access to selected rings of a ring binder, wherein,
a first of said substantially planar surfaces is flat and a second of said planar surfaces comprises a longitudinal recessed portion, said recessed portion comprising first and second longitudinally spaced locking tabs; and,
said flanged portion comprises a second of said openings being elongated to provide access to locking tabs of another USB device of same construction for locking engagement therewith, thereby allowing optimized stacking of a plurality of USB devices within a ring binder.

8. The system of claim 7, wherein:
a) a first of said substantially planar surfaces is flat and a second of said planar surfaces comprises a longitudinal recessed portion, said recessed portion comprising first and second longitudinally spaced locking tabs; and,
b) said flanged portion comprises a second of said openings being elongated to provide access to locking tabs of another USB device of same construction for locking engagement therewith, thereby allowing optimized stacking of a plurality of USB devices within a ring binder.

9. The system of claim 7, wherein said second of said openings is stepped.

10. The system of claim 7, further comprising a cap for fitting over the end of said USB element.

11. The system of claim 7, wherein said USB element comprises a memory storage device.

12. The system of claim 7, wherein said USB element comprises a digital picture frame playback device.

13. A USB device, comprising:
a) a main body comprising a first and a second opposing substantially planar surface, said main body having a cavity formed therein;
b) a USB element positioned within said cavity of said main body; and,
c) a narrow flanged portion extending from said second planar surface of said main body, said narrow flanged portion comprising at least one opening extending therethrough, wherein
i. a first of said substantially planar surfaces is flat and a second of said planar surfaces comprises a longitudinal recessed portion, said recessed portion comprising first and second longitudinally spaced locking tabs; and,
ii. said at least one opening provides access to locking tabs of another USB device of same construction for locking engagement therewith, thereby allowing optimized stacking of a plurality of USB devices.

14. The USB device of claim 13, wherein said at least one opening comprises an elongated opening.

15. The USB device of claim 14, wherein said elongated opening is stepped.

16. The USB device of claim 13, wherein said at least one opening comprises a first opening being so sized to provide access to selected rings of a ring binder and a second elongated opening to provide said access to said locking tabs of said another USB device.

17. The USB device of claim 13, further comprising a cap for fitting over the end of said USB element.

18. The USB device of claim 13, wherein said USB element comprises a memory storage device.

19. The USB device of claim 13, wherein said USB element comprises a digital picture frame playback device.

20. A system of stackable devices for use with a ring binder, comprising:
a plurality of stackable devices, said plurality of stackable devices comprising at least one USB device, said at least one USB, comprising:
a) a main body comprising a first and a second opposing substantially planar surface so as to be easily accommodated in a ring binder, said main body having a cavity formed therein;
b) a USB element positioned within said cavity of said main body; and,
c) a narrow flanged portion extending from said second planar surface of said main body, said narrow flanged portion comprising a plurality of spaced openings extending therethrough, at least one of said openings being so sized to provide access to selected rings of a ring binder, wherein,
a first of said substantially planar surfaces is flat and a second of said planar surfaces comprises a longitudinal recessed portion, said recessed portion comprising first and second longitudinally spaced locking tabs; and,
said flanged portion comprises a second of said openings being elongated to provide access to locking tabs of another stackable device of similar construction for locking engagement therewith, thereby allowing optimized stacking of a plurality of stackable devices within a ring binder.
